(19) United States
(12) Patent Application Publication
(10) Pub. No.: US 2026/0014668 A1
(43) Pub. Date: Jan. 15, 2026

(54) RETAINER RING, POLISHING HEAD ASSEMBLY INCLUDING THE RETAINER RING, AND POLISHING DEVICE INCLUDING THE POLISHING HEAD ASSEMBLY

(71) Applicant: Samsung Electronics Co., Ltd., Suwon-si (KR)

(72) Inventors: Hyungjoo LEE, Suwon-si (KR); Youngjae PARK, Suwon-si (KR); Yong-Gu KIM, Suwon-si (KR); Kyoungjin NAM, Suwon-si (KR); Eun A SHIM, Suwon-si (KR); Jae Hwan CHO, Suwon-si (KR)

(21) Appl. No.: 18/991,811

(22) Filed: Dec. 23, 2024

(30) Foreign Application Priority Data
Jul. 11, 2024 (KR) 10-2024-0091930

(51) Int. Cl. B24B 37/32

(52) U.S. Cl. CPC B24B 37/32

(57) ABSTRACT

Provided is a retainer ring including an upper ring configured to be coupled to a polishing head of a polishing device and is formed of a magnetic material, a lower ring configured to share a central axis with the upper ring, and to be attached to and detached from the upper ring, wherein the upper ring includes a plurality of first connectors, and a groove formed at an outermost radial edge of the upper ring, and the lower ring includes a plurality of second connectors that are formed at positions corresponding to the plurality of first connectors and interlocked with the plurality of first connectors, and a magnet receptacle formed on a surface facing the upper ring and configured to accommodate a magnet.

### CROSS-REFERENCE TO RELATED APPLICATION(S)

This application claims priority under 35 U.S.C. § 119 to and benefit of Korean Patent Application No. 10-2024-0091930, filed on Jul. 11, 2024, in the Korean Intellectual Property Office, the disclosure of which is incorporated herein by reference in its entirety.

### BACKGROUND

### 1. Field of the Invention

Example embodiments relate to a retainer ring, a polishing head assembly including the retainer ring, and a polishing device including the polishing head assembly.

### 2. Description of the Related Art

In order to flatten a surface of a semiconductor wafer, in a chemical mechanical polishing (CMP) process, a polishing head is equipped with a retainer ring arranged along a periphery of the semiconductor wafer, and thus the semiconductor wafer is prevented from coming off the polishing head during the process.

The retainer ring wears and may be damaged during the CMP process, and thus retainer rings should be replaced periodically.

### SUMMARY

Aspects of the disclosure provide an easily replaceable retainer ring, a polishing head assembly including the retainer ring, and a polishing device including the polishing head assembly.

The technical tasks to be achieved by the present example embodiments are not limited to the technical tasks described above, and other technical tasks will be clear from the following example embodiments by those skilled in the art.

According to an aspect, there is provided a retainer ring including an upper ring configured to be coupled to a polishing head of a polishing device and is formed of a magnetic material, a lower ring configured to share a central axis with the upper ring, and to be attached and detached from the upper ring, wherein the upper ring includes a plurality of first connectors that are arranged along a circumferential direction on a surface placed to face the lower ring when the lower ring is attached to the upper ring, and a groove formed at an outermost radial edge of the surface placed to face the lower ring when the lower ring is attached to the upper ring, and the lower ring includes a plurality of second connectors vertically overlapping the plurality of first connectors and formed on a surface placed to face the upper ring when the lower ring is attached to the upper ring, the plurality of second connectors configured to be interlocked with the plurality of first connectors, and a magnet receptacle formed on the surface placed to face when the lower ring is attached to the upper ring and configured to accommodate a magnet.

According another aspect, there is provided a retainer ring including an upper ring configured to be coupled to a polishing head of a polishing device and is formed of a magnetic material, and a lower ring configured to share a central axis with the upper ring, and to be attached and detached from the upper ring, wherein the upper ring includes a plurality of first connectors that are arranged along a circumferential direction, and a separating part configured to be suitable for a separating member to be inserted from outside, wherein a surface of the upper ring configured to face the lower ring when the lower ring is attached to the upper ring includes a first portion on which the plurality of connectors are arranged, and a first outer portion formed with a different height from the first inner portion in a direction parallel to the central axis, wherein the separating part is arranged on the first outer portion, wherein the lower ring includes a plurality of second connectors that are formed at positions vertically overlapping the plurality of first connectors when the lower ring is attached to the upper ring and are configured to be interlocked with the first connectors, and a magnet receptacle configured to accommodate a magnet, and wherein a surface of the lower ring configured to face the upper ring includes a second inner portion on which the plurality of second connectors and the magnet receptacle are arranged, and a second outer portion formed with a different height from the second inner portion in the direction parallel to the central axis.

According another aspect, there is provided a polishing head assembly including a polishing head configured to be installed in a polishing device, a membrane mounted on the polishing head, and configured to polish a substrate and press the substrate onto a polishing pad, and a retainer ring mounted on a side that the polishing head faces the polishing pad, wherein the retainer ring includes an upper ring coupled to a polishing head of a polishing device and is formed of a magnetic material, and a lower ring sharing a central axis with the upper ring, and configured to be detached from the upper ring, the upper ring includes a plurality of first connectors arranged along a circumferential direction on a surface facing the lower ring, and a groove formed at an outermost radial edge of the surface facing the lower ring, and the lower ring includes a plurality of second connectors formed at positions vertically overlapping the plurality of first connectors on a surface facing the upper ring and interlocked with the plurality of first connectors, and a magnet receptacle formed on the surface facing the upper ring and accommodating a magnet.

Additional aspects of example embodiments will be set forth in the following description and will be apparent from the description, and/or may be learned by practice of the disclosure.

According to example embodiments, it is possible to easily replace retainer rings.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a conceptual diagram illustrating a polishing device according to an example embodiment;

FIG. 2 is a schematic drawing of a polishing head assembly according to an example embodiment;

FIG. 3 is a drawing illustrating a lower ring being removed from a polishing head assembly according to an example embodiment;

FIG. 4 is a drawing illustrating a lower ring by looking through an upper ring of a retainer ring according to an example embodiment;

FIG. 5 is a drawing illustrating an upper ring included in a retainer ring according to an example embodiment;

FIG. 6 is a drawing illustrating the opposite side of the upper ring illustrated in FIG. 5;

FIG. 7 is a drawing illustrating a lower ring included in a retainer ring according to an example embodiment;

FIG. 8 is a drawing illustrating the opposite side of the lower ring illustrated in FIG. 7;

FIG. 9 is a drawing illustrating a cross-section taken along line I-I′ of FIG. 4 according to an example embodiment;

FIG. 10 is a drawing illustrating a cross-section taken along line II-II′ of FIG. 4 according to an example embodiment;

FIG. 11 is a drawing exemplarily illustrating a cross-section taken along line II-II′ of FIG. 4 according to an example embodiment;

FIG. 12 is a drawing illustrating a lower ring according to an example embodiment;

FIG. 13 is a drawing illustrating a cross-section taken along line III-III′ of FIG. 12 according to an example embodiment;

FIG. 14 is a drawing illustrating a cross-section taken along line IV-IV′ of FIG. 12 according to an example embodiment;

FIG. 15 is a conceptual drawing of a polishing head assembly according an example embodiment; and

FIG. 16 is a conceptual drawing of a polishing head assembly according to an example embodiment.

### DETAILED DESCRIPTION

Prior to the detailed description of the present disclosure, it should be pointed out that terms or words used in the specification and claims should not be construed as limited to their common or dictionary meanings. Further, the terms or words should be interpreted with meaning and concept consistent with the technical idea of the present disclosure based on the principle that the inventor may appropriately define the concept of terms in order to explain his or her invention in the best way. The example embodiments described in this specification and the configurations shown in the drawings are only the most preferred embodiments of the present disclosure, and do not necessarily represent the entire technical idea of the present disclosure. Accordingly, at the time of filing the present disclosure, there may be various equivalents and modifications that can replace them.

The same reference numerals or signs shown in respective drawings attached to the specification may represent parts or components that perform the same or substantially the same functions. For convenience of description and understanding, different embodiments may be described using the same reference numerals or symbols. For example, even if a component or an element having the same reference numeral is shown in multiple drawings, the multiple drawings may not all represent one example embodiment.

In the following description, singular expressions may represent or include plural expressions unless the context clearly indicates otherwise. It will be understood that, when an element (for example, a first element) is “(operatively or communicatively) coupled with/to” or “connected to” another element (for example, a second element), the element may be directly coupled with/to the other element, or there may be an intervening element (for example, a third element) between the element and the other element. The terms “have,” “may have,” “include,” and “may include” as used herein indicate the presence of corresponding features (for example, elements such as numerical values, functions, operations, or parts), and do not preclude the presence of additional features.

Further, in the following description, expressions such as an upper side, top, a lower side, bottom, a side, front and a back side are expressed based on the direction shown in the drawings. If the direction of the object changes, it may be expressed differently.

Further, in the description below, the expressions “first direction D1,” “second direction D2” and “third direction D3” can correspond to the X-axis direction, the Y-axis direction, and the Z-axis direction defining three-dimensional space, but the present disclosure is not limited thereto. As the definition of one direction (for example, the first direction) changes, the remaining directions (for example, the second direction and the third direction) can also be changed correspondingly.

Further, in the specification and claims, terms including ordinal numbers such as “first,” “second,” etc. may be used to distinguish between components or elements. These ordinal numbers are used to distinguish identical or similar components from each other, and the meaning of the terms should not be interpreted limitedly due to the use of such ordinal numbers. For example, components or elements combined with these ordinal numbers should not be interpreted as having a limited order of use or arrangement based on the numbers. If necessary, each ordinal number may be used interchangeably.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Hereinafter, example embodiments of the present disclosure will be described in detail with reference to the attached drawings. However, the spirit of the present disclosure is not limited to the example embodiments. For example, a person skilled in the art who understands the spirit of the present disclosure may suggest other example embodiments that are included within the scope of the spirit of the present disclosure through addition, change, or deletion of components or elements: however, such example embodiments are intended to be included within the scope of the present disclosure. The shapes and sizes of elements in the drawings may be exaggerated for clearer explanation/understanding.

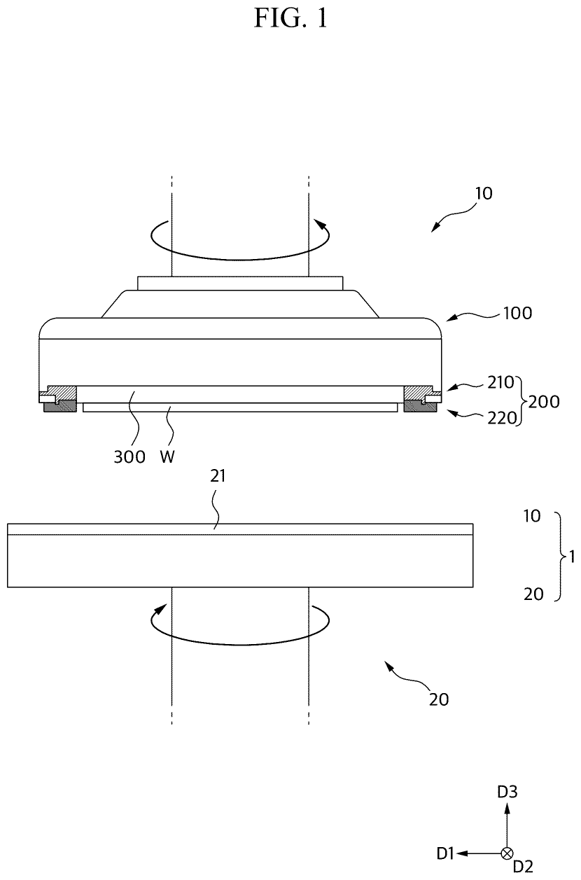

FIG. 1 is a conceptual diagram illustrating a polishing device 1 according to an example embodiment.

Referring to FIG. 1, the polishing device 1 according to the example embodiment may include a polishing head assembly 10 and a polishing table 20.

According to some example embodiments, the polishing table 20 may be equipped with a polishing pad 21. The polishing pad 21 may be used for a polishing process performed on semiconductor substrates. The surface of the polishing pad may be formed of soft or fine vellum, paper, polyurethane or fiber. The polishing pad may not have a polishing function in itself, but may have a polishing function through an aid of a separately supplied slurry. The polishing pad 21 and the polishing table 20 may be disc-shaped. The polishing table 20 may be rotatable. The polishing table 20 may rotate clockwise or counterclockwise while a polishing process is performed. During a polishing process, the direction of rotation of the polishing table 20 may be opposite to a direction of rotation of the polishing head assembly 10. During the polishing process, as the polishing table 20 rotates, an upper surface of the polishing pad 21 may come into contact with a lower surface of a substrate W held by the polishing head assembly 10 to polish the substrate W.

According to some example embodiments, the polishing head assembly 10 may include a polishing head 100, a retainer ring 200 and a membrane 300.

According to some example embodiments, the polishing head 100 may approach or move away (e.g., recede) from the polishing pad 21. The polishing head 100 may be rotated. The polishing head 100 may rotate counterclockwise or clockwise. The relative rotation speed of the polishing head 100 to the polishing table 20 may vary over time. Even though not illustrated, the polishing head 100 may move horizontally on the polishing pad 21 (on a plane parallel to the D1-D2 plane). The surface facing the polishing pad 21 of the polishing head 100 may be equipped with the membrane 300 and the retainer ring 200. The membrane 300 may pressurize the substrate W onto the polishing pad 21. The membrane 300 may hold or release the substrate W by vacuum on the lower surface of the polishing head 100. The membrane 300 may control the polishing rate of the substrate W by applying and/or increasing/reducing pressure to the substrate W. The retainer ring 200 may wrap around the perimeter of the substrate. During the polishing process, the retainer ring 200 may prevent the substrate W from being separated from the polishing head assembly 10.

Even though not illustrated in the drawings, according to some example embodiments, the polishing device 1 may include a conditioner configured to polish a portion of the polishing pad 21 and/or a slurry supply unit configured to supply slurry for polishing.

Below, the retainer ring 200 according to some embodiments is described in more detail.

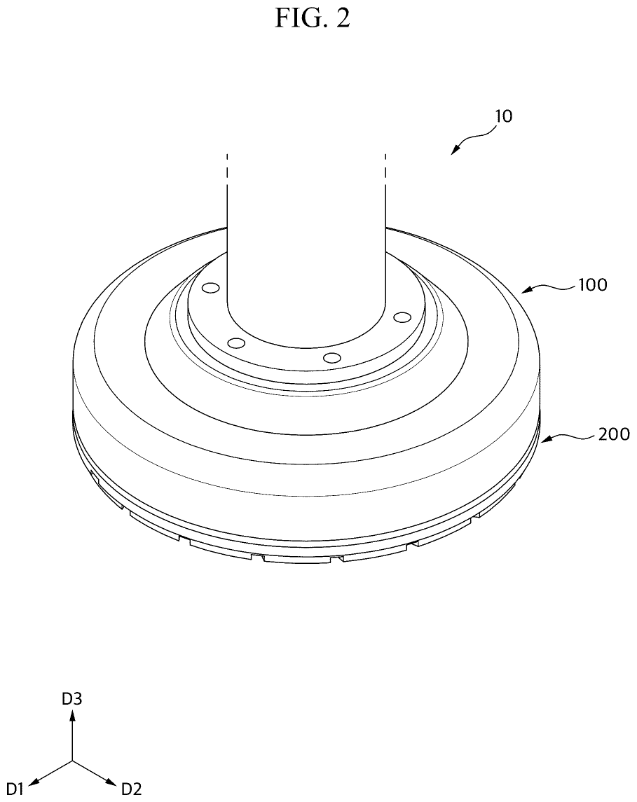

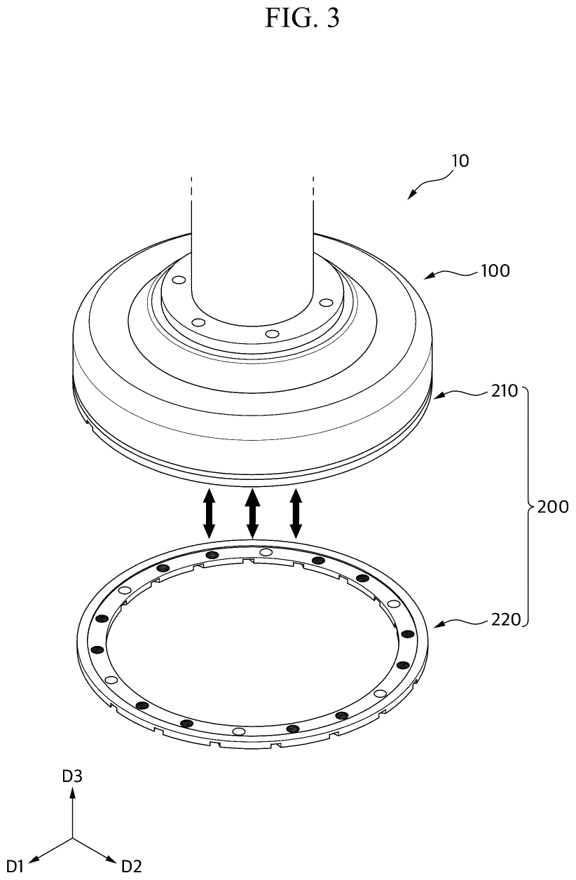

FIG. 2 is a schematic drawing of the polishing head assembly 10 according to an example embodiment. FIG. 3 is a drawing illustrating a lower ring 220 being removed from the polishing head assembly 10 according to an example embodiment.

Referring to FIG. 2 and FIG. 3, the retainer ring 200 may include an upper ring 210 and the lower ring 220.

According to some example embodiments, the upper ring 210 may be coupled to the polishing head 100. The upper ring 210 may be formed of a magnetic material. For example, the upper ring 210 may be made of metal. The lower ring 220 may share the central axis with the upper ring 210. For example, an axis passing through a center of the lower ring 220 in a vertical direction (D3) may overlap an axis passing through a center of the upper ring 210 in the vertical direction when the upper ring 210 and the lower ring 220 are combined with each other. The lower ring 220 may be detached from the upper ring 210. For example, the lower ring 220 may be made of resin.

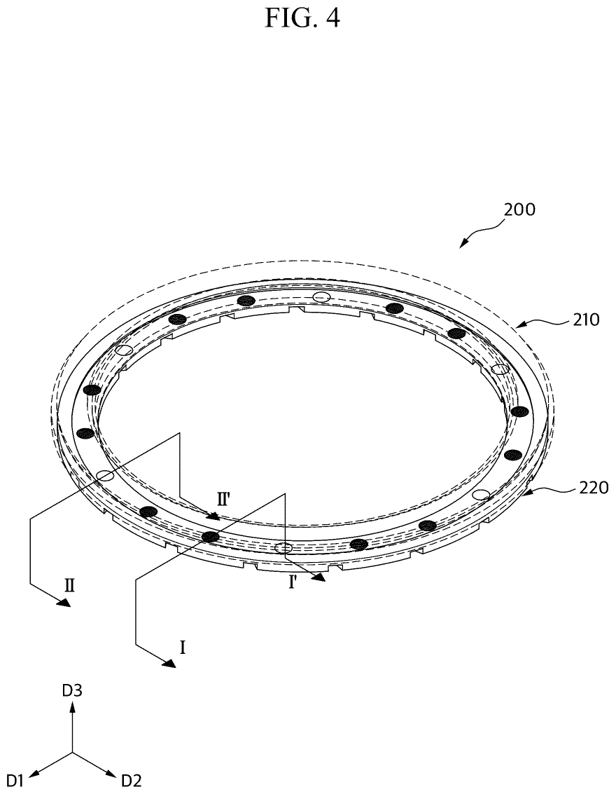

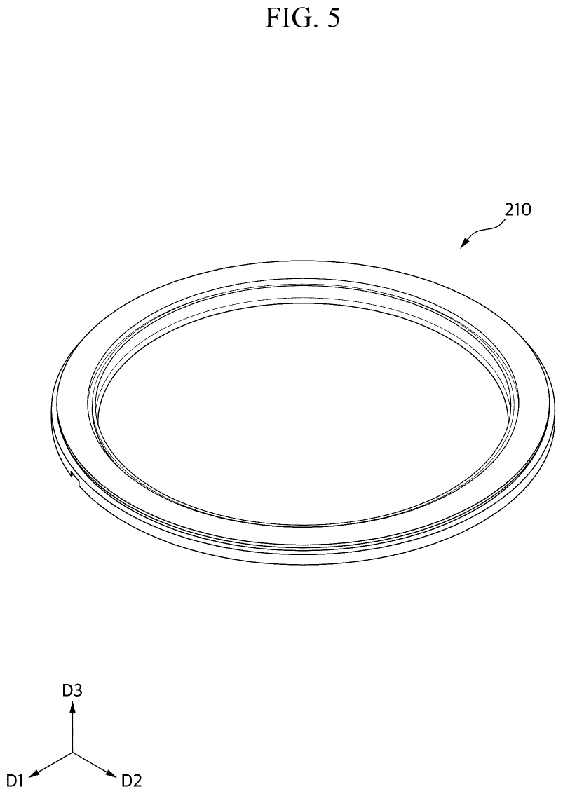

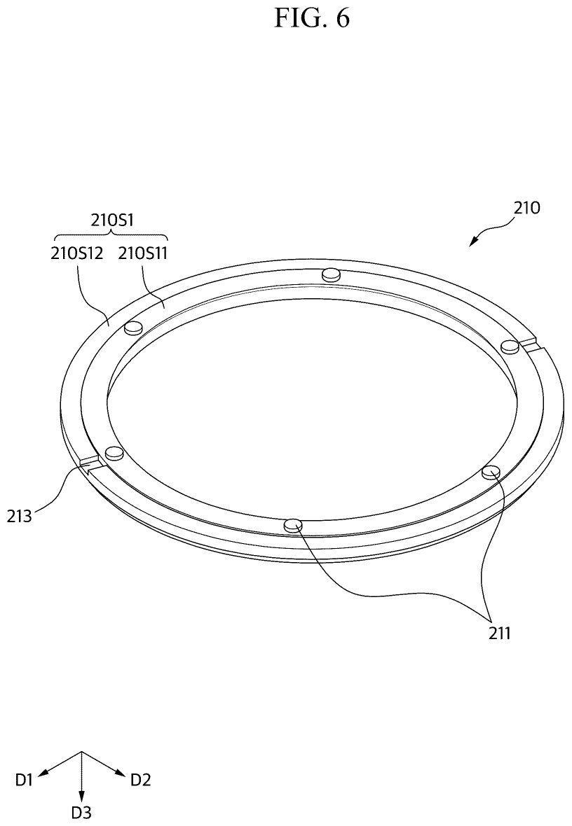

FIG. 4 is a drawing illustrating the lower ring 220 shown through the upper ring 210 of the retainer ring 200 according to an example embodiment. FIG. 5 is a drawing (a perspective view) illustrating the upper ring 210 included in the retainer ring 200 according to an example embodiment. FIG. 6 is a drawing illustrating the opposite side of the upper ring 210 illustrated in FIG. 5. For example, FIG. 6 is perspective view of the upper ring 210 shown in FIG. 5 with a posture turned upside down.

Referring to FIG. 5 and FIG. 6 together with FIG. 4, the upper ring 210 may include a plurality of first fixing parts 211 and separating parts 213.

According to some example embodiments, the plurality of first fixing parts 211 may be arranged circumferentially on one side (e.g., on a lower surface) 210S1 facing the lower ring 220. The plurality of first fixing parts 211 may be arranged at equal intervals along the circumferential direction. The first fixing parts 211 may have shapes corresponding to shapes of second fixing parts 221 of the lower ring 220 described later. For example, each of the first fixing parts and the second fixing parts may be a connector or a coupler. The connector or the coupler may be a link interconnecting/interlocking a corresponding pair of a first fixing part 211 and a second fixing part 221 with each other. For example, one of the corresponding pair of the first fixing part 211 and the second fixing part may be a plug, and the other of the corresponding pair of the first fixing part 211 and the second fixing part may be a socket configured such that the plug and the socket are interconnected/interlocked with each other.

According to some example embodiments, the separating parts 213 may be formed on the outermost radial edge of one side 210S1 facing the lower ring 220. The separating parts 213 may have a groove shape formed along the radial direction of the upper ring 210. For example, the separating parts 213 may be a groove shape that is open through the exterior of the upper ring 210. For example, the separating parts 213 may be grooves or recesses formed on the lower surface 210S1 of the upper ring 210. The separating parts 213 may be open to an outer circumferential surface of the upper ring 210. When the upper ring 210 is coupled to the lower ring 220, a separating member may be inserted into the separating parts 213 to separate the lower ring 220 from the upper ring 210. For example, the separating member may be a lever (e.g., a bar such as a pry bar formed of metal or other materials) inserted into a groove or a recess of the separating parts 213. For example, groove shapes and grooves described in the present disclosure may be indentations formed on surfaces of parts or components. While the grooves and the groove shapes may be elongated like a trench or an elliptical indentation in certain embodiments, the grooves and the groove shapes need not be elongated and may have a length dimension equal to or substantially the same as its width dimension as in a cylindrical indentation or a square indentation. In addition, it should be appreciated that the groove may be a hole that fully penetrates a part/component (the upper ring 210 or the lower ring 220) or an indentation that only partially extends from a surface into a part/component (the upper ring 210 or the lower ring 220).

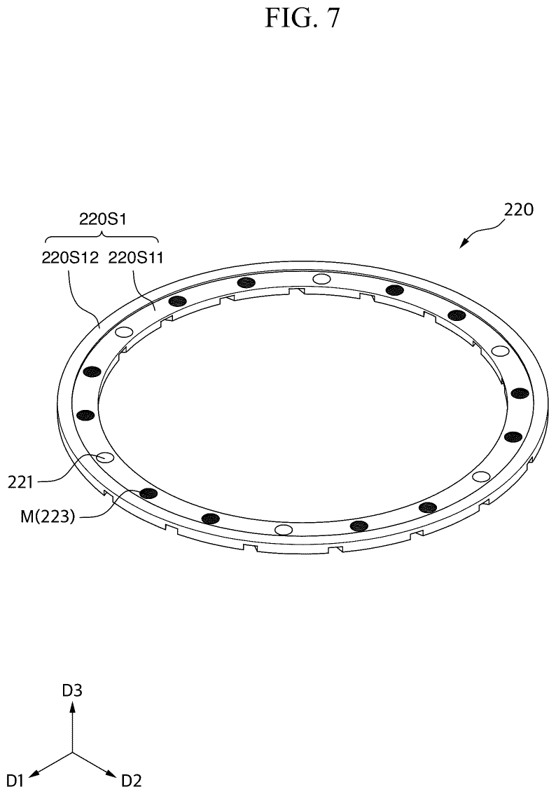

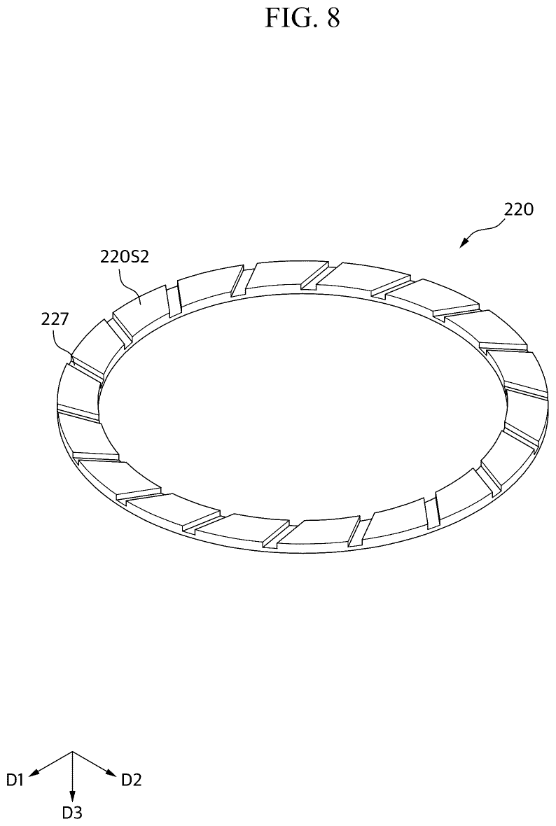

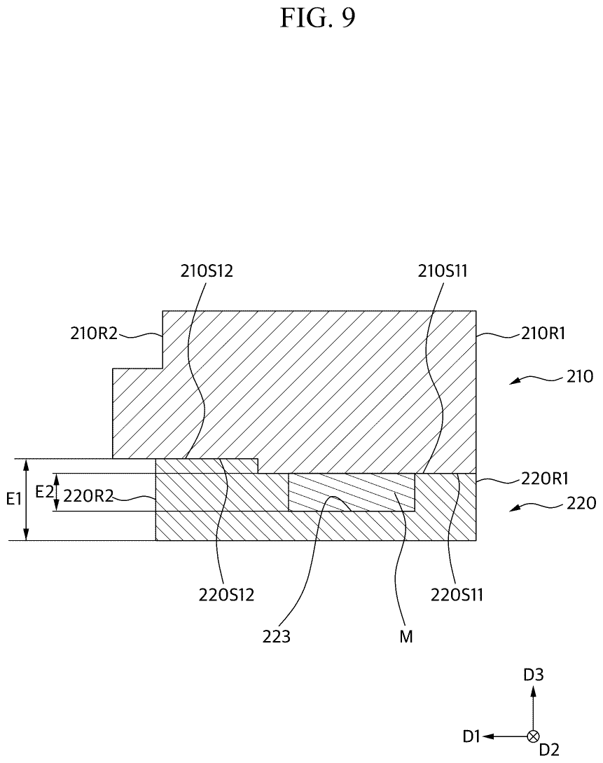

FIG. 7 is a drawing illustrating the lower ring 220 included in the retainer ring 200 according to an example embodiment. FIG. 8 is a drawing illustrating the opposite side of the lower ring 220 illustrated in FIG. 7. For example, FIG. 8 is perspective view of the lower ring 220 shown in FIG. 7 with a posture turned upside down. FIG. 9 is a drawing illustrating an example embodiment and showing a cross-section taken along line I-I′ of FIG. 4.

Referring to FIG. 7 to FIG. 9 together with FIG. 4, the lower ring 220 may include the plurality of second fixing parts 221 and magnet receptacles 223.

According to some example embodiments, when viewed from the axial direction (the direction D3) of the lower ring 220, the plurality of second fixing parts 221 may be formed at positions corresponding to, or overlapping with, the plurality of first fixing parts 211. For example, each of the second fixing parts 221 may vertically overlap a corresponding one of the first fixing parts 211 when the upper ring 210 and the lower ring 220 are combined with each other. The plurality of second fixing parts 221 may be arranged at equal intervals along the circumference. The number of second fixing parts 221 and the number of first fixing parts 211 may be the same. The second fixing parts 221 may be interlocked with the first fixing parts 211.

According to some example embodiments, the magnet receptacles 223 may be formed on one side (e.g., an upper surface) 220S1 facing the upper ring 210. The magnet receptacles 223 have a groove shape and may accommodate a magnet M. For example, the magnet receptacles 223 may be grooves formed on the upper surface 220S1 of the lower ring 220. For example, the lower surface 210S1 of the upper ring 210 and the upper surface 220S1 of the lower ring 220 may contact each other when the lower ring 220 is attached to the upper ring 210 to form the retainer ring 200. The magnet receptacles 223 may be arranged at equal intervals along the circumference between adjacent pairs of the plurality of second fixing parts 221. By arranging the magnet receptacles 223 at equal intervals, the upper ring 210 and the lower ring 220 may be uniformly coupled to each other. When the upper ring 210 and the lower ring 220 are coupled to each other and a cohesion of a specific area needs to be increased, the magnet receptacles 223 may be concentrated in the specific area. Based on the direction of the central axis (in the direction parallel to the D3 axis), the depth E2 of the magnet receptacles 223 may be less than or equal to 0.5 times the maximum thickness E1 of the lower ring 220. The depth E2 of the magnet receptacles 223 in the central axis direction may be greater than 0.5 times the thickness of the substrate W. In the direction of the central axis, the depth E2 of the magnet receptacles 223 may be less than twice the thickness of the substrate W. If the depth E2 of the magnet receptacles 223 is formed too deep, the thickness of the part where the magnet receptacles 223 of the lower ring 220 are provided may be reduced, thereby weakening the strength, and during the polishing process, the underside (e.g., bottom surface) of the lower ring 220 may be polished, which may result in the required minimum retention thickness not being achieved/maintained.

According to some example embodiments, the thickness of the magnet M may be equal to the depth E2 of magnet receptacles 223. The thickness of the magnet M may be less than the depth E2 of magnet receptacles 223. The magnet M accommodated in the magnet receptacles 223 may be fixed to the inside of the magnet receptacles 223 by an adhesive.

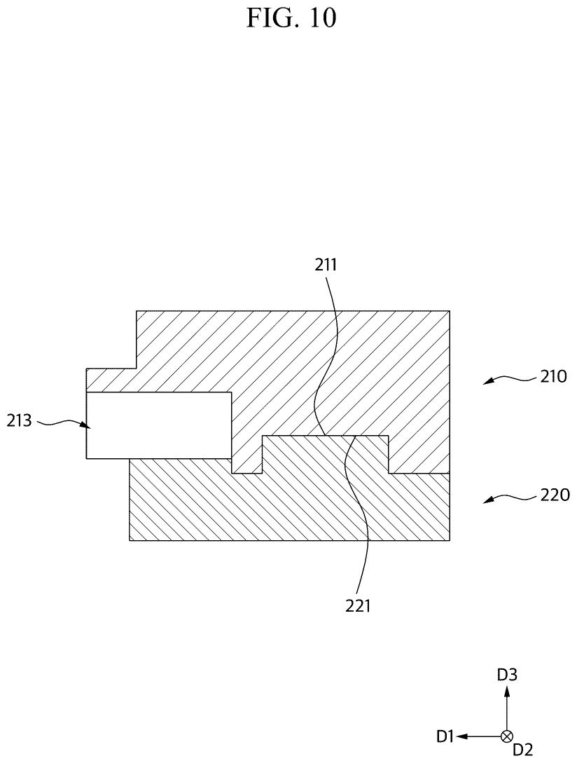

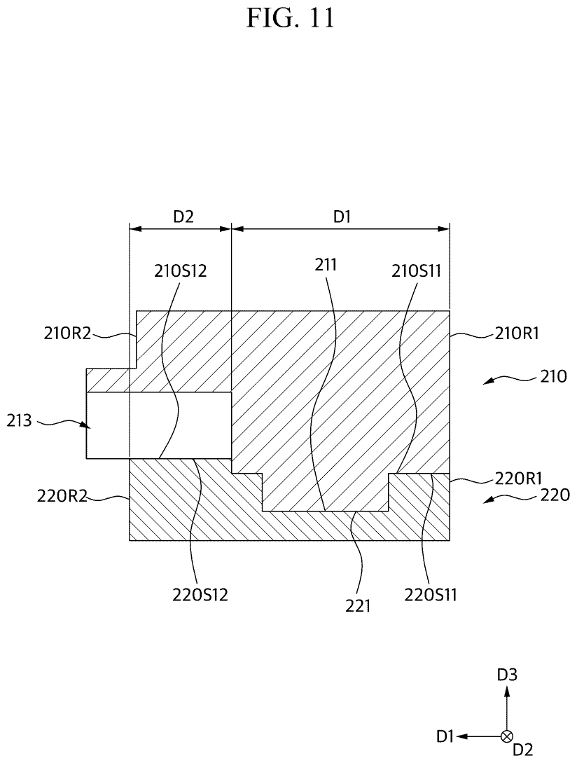

FIG. 10 is a drawing illustrating a cross-section taken along line II-II′ of FIG. 4 according to an example embodiment. FIG. 11 is a drawing exemplarily illustrating a cross-section according to another example embodiment that is different from the example embodiment illustrated in FIG. 10.

As described above, the first fixing parts 211 and the second fixing parts 221 may be configured to interlock with each other. For example, as illustrated in FIG. 11, when the first fixing parts 211 are protrusions protruding toward the lower ring 220, the second fixing parts 221 may be grooves/holes configured to engage with the plurality of first fixing parts 211. For example, the protrusions of the first fixing parts 211 may be inserted into the holes/grooves of the second fixing parts 221 when the upper ring 210 and the lower ring 220 are combined with each other. Alternatively, as illustrated in FIG. 10, when the second fixing parts 221 are protrusions protruding toward the upper ring 210, the first fixing parts 211 may be grooves/holes configured to engage with the plurality of second fixing parts 221. For example, the protrusions of the second fixing parts 221 may be inserted into the holes/grooves of the first fixing parts 211 when the upper ring 210 and the lower ring 220 are combined with each other. For example, the first fixing parts 211 and the second fixing parts 221 may be latches/locks interlocked with each other when the upper ring 210 and the lower ring 220 are combined with each other, and may be called first latches/locks and second latches/locks respectively.

According to the configuration of the example embodiments, the installation/combining of the upper ring 210 and the lower ring 220 through the magnet M and the removal of the upper ring 210 and the lower ring 220 through the separating parts 213 may be facilitated. In the polishing process, the retainer ring 200 may require periodic replacement due to contamination by slurry or due to damage by contact with the polishing pad 21 together with the substrate W. However, if the retainer ring 200 is not easily replaceable from the polishing head 100, the entire polishing process including replacement of the retainer ring 200 may take longer and/or unintentional damage may occur to the polishing head 100 during the replacement of the retainer ring 200.

Further, replacing the retainer ring 200 may require removal of other components of the polishing head assembly 10, such as the membrane 300. In this case, during the process of replacing the retainer ring 200, other components may become contaminated with the slurry, and thus there may be cases where other components should be replaced together with the replacement cycle of the retainer ring 200. If other components are replaced in accordance with the replacement cycle of the retainer ring 200, which usually has a short replacement cycle, the cost of the polishing process may increase significantly. In the present disclosure, this problem may be solved by configuring the lower ring 220 to be easily detached from the upper ring 210. The coupling strength between the upper ring 210 and the lower ring 220 may be adjusted by adjusting the number of magnet receptacles 223 and the magnet M, or changing the magnetic force of the magnet M. Even in the case where the upper ring 210 and the lower ring 220 are strongly coupled, the lower ring 220 coupled to the upper ring 210 may be easily separated from the upper ring 210 by using the separating parts 213 and separating members when needed, and the lower ring 220 be replaced easily and readily. By easily replacing only the lower ring 220, which has the shortest replacement cycle, the time and cost of the polishing process will be reduced.

Referring to FIG. 6, FIG. 7, FIG. 9 and FIG. 11, the upper ring 210 and the lower ring 220 may have step structures on sides/surfaces (the one side (e.g., the lower surface) 210S1 or the upper ring 210 and the one side (e.g., the upper surface) 220S1 of the lower ring 220) facing each other.

According to some example embodiments, the one side (or a lower surface) 210S1 of the upper ring 210 facing the lower ring 220 may include a first inner side 210S11 and a first outer side 210S12. For example, the first inner side 210S11 may be an inner portion of the lower surface of the upper ring 210 as shown in FIG. 11 and may be called a first inner portion, and the first outer side 210S12 may be an outer portion of the upper ring 210 as shown in FIG. 11 and may be called a first outer portion. The first inner side 210S11 may be adjacent to an inner side surface 210R1 of the upper ring 210. The plurality of first fixing parts 211 may be arranged on the first inner side 210S11. The first outer side 210S12 may be adjacent to an outer side surface 210R2 of the upper ring 210. The first outer side 210S12 may be formed with a different height from the first inner side 210S11 along the central axis or in a vertical direction. The separating parts 213 may be arranged on the first outer side 210S12. The first outer side 210S12 may have a higher height along the central axis or in the vertical direction than the first inner side 210S11. However, the first outer side 210S12 may form a step structure with a lower height along the central axis or in the vertical direction than the first inner side 210S11 in certain embodiments.

According to some example embodiments, the one side (or an upper surface) 220S1 of the lower ring 220 facing the upper ring 210 may include a second inner side 220S11 and a second outer side 220S12. For example, the second inner side 220S11 may be an inner portion of the upper surface of the lower ring 220 as shown in FIG. 11 and may be called a second inner portion, and the second outer side 220S12 may be an outer portion of the lower ring 220 as shown in FIG. 11 and may be called a second outer portion. The second inner side 220S11 may be adjacent to an inner side surface 220R1 of the lower ring 220. The plurality of second fixing parts 221 may be arranged on the second inner side 220S11. The magnet receptacles 223 may be arranged on the second inner side 220S11. The second outer side 220S12 may be adjacent to an outer side surface 220R2 of the lower ring 220. The second outer side 220S12 may be formed with a different height from the second inner side 220S11 along the central axis or in the vertical direction. The second outer side 220S12 may have a higher height along the central axis or in the vertical direction than the second inner side 220S11. However, in case the height of the first outer side 210S12 along the central axis or in the vertical direction (D3) is lower than that of the first inner side 210S11, the second outer side 220S12 may have a lower height along the central axis or in the vertical direction than the second inner side 220S11 to correspond to the step structure of the upper ring 210.

According to some example embodiments, the width of the second inner side 220S11 along/in the radial direction may be greater than the width of the second outer side 220S12.

According to the configuration of the example embodiments, the upper ring 210 and the lower ring 220 may be more stably coupled through the step structure. For example, when a force is applied in the negative direction of D1 axis in the upper ring 210, and in the positive direction of D1 axis to the lower ring 220, the retainer ring 200 may provide stable resistance. Further, the width of the second inner side 220S11, where the magnet receptacles 223 are provided, is sufficiently secured, and thus the width of the magnet receptacles 223 may also be sufficiently secured. Therefore, since the magnet M accommodated in the magnet receptacles 223 has a large contact area with the upper ring 210 of the magnetic material, the lower ring 220 may be stably coupled to the upper ring 210.

Referring back to FIG. 4 and FIG. 8, the lower ring 220 may include a slurry moving part 227. The slurry moving part 227 may be formed on the other side (e.g., a lower surface) 220S2 located opposite to the one side (or the upper surface) 220S1 facing the upper ring 210. The slurry moving part 227 may be connected to the inner and outer sides of the lower ring 220, e.g., in a redial direction. For example, the slurry moving part 227 may be configured to communicate with a portion of the inner side and a portion of the outer side of the lower ring 220. For example, the slurry moving part 227 may be a groove (e.g., a slurry groove) formed on a lower surface of the lower ring 220 such that the slurry groove is connected from the inner side surface 220R1 to the outer side surface 220R2 of the lower ring 220 so that the slurry used in the polishing process is discharged from the inside of the retainer ring 200 to the outside of the retainer ring 200 through the slurry groove. For example, the lower ring 220 may include a plurality of slurry grooves (slurry moving parts 227) on the lower surface 220S2.

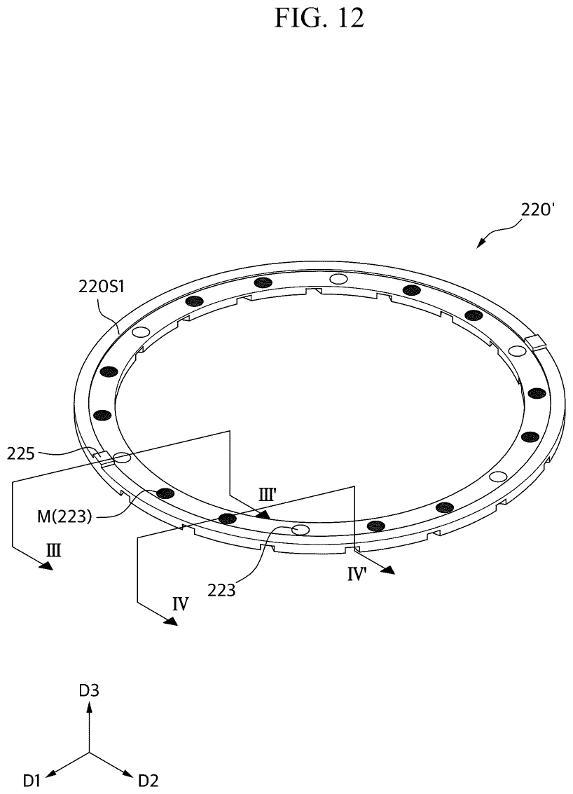

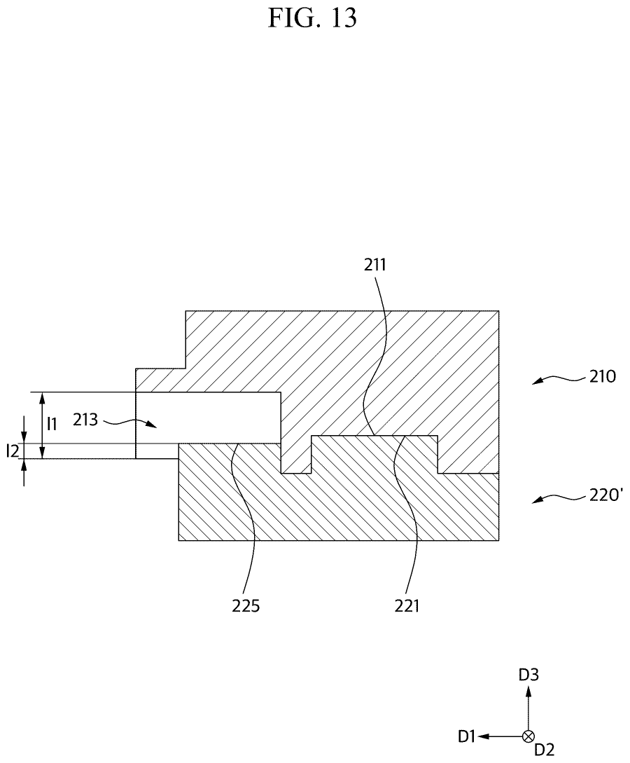

FIG. 12 is a drawing illustrating a lower ring 220′ according to another example embodiment. FIG. 13 is a drawing illustrating a cross-section taken along line III-III′ of FIG. 12 according to an example embodiment.

Referring to FIG. 12 and FIG. 13, the lower ring 220′ may further include a protruding part 225.

According to some example embodiments, the protruding part 225 may be formed on one side (e.g., an upper surface) 220S1 of the lower ring 220′ facing the upper ring 210. The protruding part 225 may be formed on the outermost radial edge of the one side (or the upper surface) 220S1 of the lower ring 220′ facing the upper ring 210. The protruding part 225 may be formed at a position corresponding to or vertically overlapping the separating parts 213 of the upper ring 210. The protruding part 225 may protrude toward the upper ring 210. For example, when FIG. 13 is referred to together with FIG. 10 or FIG. 11 for comparison, the protruding part 225 may be formed to protrude from the lower ring 220′ toward the upper ring 210 into a corresponding one of the separating parts 213. For example, each of protruding parts 225 may be a protrusion inserted into a corresponding separating part 213 when the upper ring 210 and the lower ring 220′ are combined with each other. The protruding length/height 12 of the protruding part 225 (e.g., in a vertical direction) may be shorter than the depth 11 of the separating parts 213. Accordingly, there may be a space left in the separating parts 213 into which a separating member may be inserted, e.g., to separate the lower ring 220′ from the upper ring 210.

According to the configuration of the above example embodiment, the alignment of the upper ring 210 and the lower ring 220 along the circumference may be easily achieved through the protruding part 225. When the upper ring 210 and the lower ring 220′ are combined or coupled to each other, the positions of the protruding parts 225 and the separating parts 213 may be aligned to each other at the outermost radial edge and the protruding parts 225 may be fitted into the separating parts 213 without checking the positions of the first fixing parts 211 and the second fixing parts 221. In this case, the first fixing parts 211 and the second fixing parts 221 are also interlocked, thereby facilitating alignment between the upper ring 210 and the lower ring 220′.

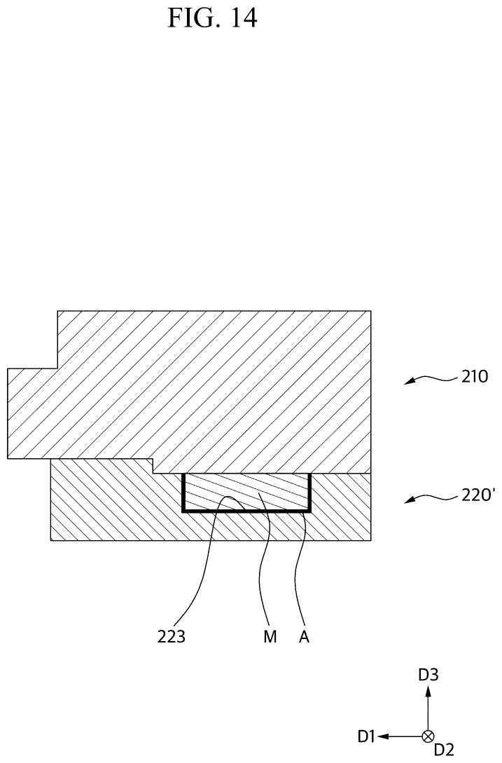

FIG. 14 is a drawing illustrating a cross-section taken along line IV-IV′ of FIG. 12 according to an example embodiment. Referring to FIG. 14, the lower ring 220′ may further include a magnetic shield A.

According to some example embodiments, the magnetic shield A may be formed on the bottom surface of the magnet receptacles 223. The magnetic shield A may be formed on the inside of the magnet receptacles 223 (e.g., on bottom surfaces and side surfaces of the magnet receptacles 223). The magnetic shield A may surround/cover at least a portion of the magnet M accommodated in the magnet receptacles 223. For example, the magnetic shield A may contact side surfaces and bottom surfaces of the magnet M accommodated in the magnet receptacles 223. However, the magnetic shield A may not surround surfaces that the magnets M accommodated in the magnet receptacles 223 are exposed toward the upper ring 210. For example, the magnetic shield A may not cover top surfaces of the magnets M.

According to the configuration of the above example embodiment, the effect of the magnet M accommodated in the magnet receptacles 223 on the equipment measuring the polishing degree of the substrate W may be minimized. The equipment for measuring the polishing degree of the substrate W may be an end point detection (EPD) measuring equipment. The EPD measuring equipment measures the polishing degree of thin-thickness substrates W, and thus the EPD measuring equipment may be affected by even the slight magnetic field of a magnet. Specifically, in the EPD measuring equipment according to a method of monitoring the voltage and current of RF waves generated by the RF generator system, the effect of the magnet's magnetic field may interfere the measurement. However, according to the configuration of the above example embodiment, by shielding the magnetic field, which is generated from the magnet M accommodated in the magnet receptacles 223 and directed to the EPD measuring equipment located on the polishing pad 21 side, with the magnetic shield A, the effect of the magnet M on the EPD measuring equipment may be minimized.

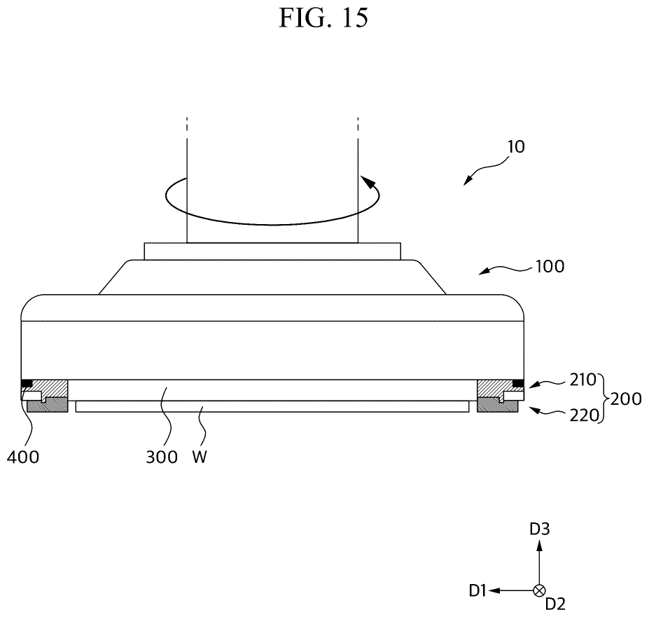

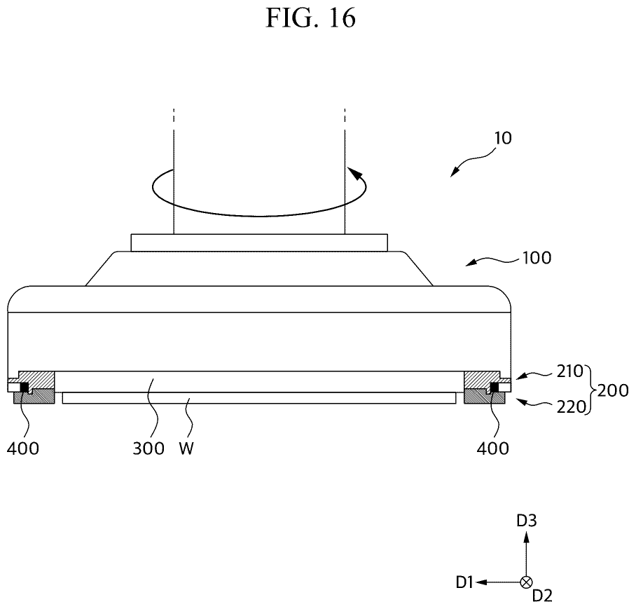

FIG. 15 is a conceptual drawing of a polishing head assembly according to another example embodiment. FIG. 16 is a conceptual drawing of a polishing head assembly according to another example embodiment that is different from the example embodiment illustrated in FIG. 15. Referring to FIG. 15 and FIG. 16, the polishing head assembly 10 may further include an O-ring 400.

According to some example embodiments, the O-ring 400 may be fitted between the retainer ring 200 and the polishing head 100. By placing the O-ring 400 between the polishing head 100 and the retainer ring 200, e.g., between the polishing head 100 and the upper ring 210, the polishing head 100 may be prevented from being damaged by the penetration of a solution or slurry used in the polishing process through the space between the polishing head 100 and the upper ring 210.

According to some example embodiments, the O-ring 400 may be placed between the upper ring 210 and the lower ring 220. By placing the O-ring 400, damage to the polishing head 100 due to penetration of a solution or slurry that may be used during the polishing process between the upper ring 210 and the lower ring 220 may be effectively prevented.

In FIG. 15, it is illustrated that the O-ring 400 is placed between the retainer ring 200 and the polishing head 100, and in FIG. 16, it is illustrated that the O-ring 400 is placed between the upper ring 210 and the lower ring 220. However, the O-ring 400 may be placed both between the retainer ring 200 and the polishing head 100 and between the upper ring 210 and the lower ring 220.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

The example embodiments of the present disclosure are described with reference to the attached drawings. However, the present disclosure is not limited to the example embodiments, and the present disclosure can be manufactured in various other forms, and a person skilled in the art to which the present disclosure pertains will understand that the present disclosure can be implemented in other specific forms without changing its technical idea or essential features. Therefore, the example embodiments described above should be understood in all respects as illustrative and not limiting.

What is claimed is:

1. A retainer ring comprising:
an upper ring configured to be coupled to a polishing head of a polishing device and is formed of a magnetic material; and
a lower ring configured to share a central axis with the upper ring, and to be attached to and detached from the upper ring,
wherein the upper ring comprises:
a plurality of first connectors that are arranged along a circumferential direction on a surface placed to face the lower ring when the lower ring is attached to the upper ring; and
a groove formed at an outermost radial edge of the surface placed to face the lower ring when the lower ring is attached to the upper ring, and
wherein the lower ring comprises:
a plurality of second connectors vertically overlapping the plurality of first connectors and formed on a surface placed to face the upper ring when the lower ring is attached to the upper ring, the plurality of second connectors configured to be interlocked with the plurality of first connectors; and
a magnet receptacle formed on the surface placed to face the upper ring when the lower ring is attached to the upper ring and configured to accommodate a magnet.

2. The retainer ring of claim 1, wherein the lower ring further comprises a protrusion formed on the surface placed to face the upper ring at a position vertically overlapping the groove of the upper ring when the lower ring is attached to the upper ring.

3. The retainer ring of claim 2, wherein the protrusion has a height shorter than a depth of the groove.

4. The retainer ring of claim 1, wherein the lower ring further comprises a magnetic shield formed on a bottom of the magnet receptacle.

5. The retainer ring of claim 4, wherein the magnetic shield is formed on a bottom surface and a side surface of the magnet receptacle.

6. The retainer ring of claim 1, wherein the magnet has a thickness that is less than or equal to a depth of the magnet receptacle.

7. The retainer ring of claim 1, wherein the first connectors are protrusions protruding toward the lower ring when the lower ring is attached to the upper ring, and
wherein the second connectors are grooves configured to be interlocked with the first connectors.

8. The retainer ring of claim 1, wherein the second connectors are protrusions protruding toward the upper ring when the lower ring is attached to the upper ring, and
wherein the first connectors are grooves configured to be interlocked with the second connectors.

9. The retainer ring of claim 1, wherein the plurality of first connectors of the upper ring are arranged at equal intervals along the circumferential direction, and
wherein the plurality of second connectors of the lower ring are arranged at equal intervals along the circumferential direction.

10. The retainer ring of claim 9, wherein a plurality of magnet receptacles are arranged at equal intervals along the circumferential direction between adjacent pairs of the plurality of second connectors.

11. The retainer ring of claim 1, wherein the upper ring is made of metal, and
wherein the lower ring is made of resin.

12. The retainer ring of claim 1, wherein the lower ring comprises a slurry groove provided on a surface opposite the surface placed to face the upper ring when the lower ring is attached to the upper ring, and
wherein the slurry groove connects a portion of an outer side and a portion of an inner side of the lower ring.

13. A retainer ring comprising:
an upper ring configured to be coupled to a polishing head of a polishing device and is formed of a magnetic material; and
a lower ring configured to share a central axis with the upper ring, and to be attached to and detached from the upper ring,
wherein the upper ring comprises:
a plurality of first connectors that are arranged along a circumferential direction; and
a separating part configured to be suitable for a separating member to be inserted from outside,
wherein a surface of the upper ring configured to face the lower ring when the lower ring is attached to the upper ring comprises:
a first inner portion on which the plurality of first connectors are arranged; and
a first outer portion formed with a different height from the first inner portion in a direction parallel to the central axis,
wherein the separating part is arranged on the first outer portion,
wherein the lower ring comprises:
a plurality of second connectors formed at positions vertically overlapping the plurality of first connectors when the lower ring is attached to the upper ring and are configured to be interlocked with the first connectors; and
a magnet receptacle configured to accommodate a magnet, and
wherein a surface of the lower ring configured to face the upper ring when the lower ring is attached to the upper ring comprises:
a second inner portion on which the plurality of second connectors and the magnet receptacle are arranged; and
a second outer portion formed with a different height from the second inner portion in the direction parallel to the central axis.

14. The retainer ring of claim 13, wherein the second inner portion has a width in a radial direction that is greater than a width of the second outer portion in the radial direction.

15. The retainer ring of claim 13, wherein the magnet receptacle has a depth in the direction parallel to the central axis that is less than or equal to 0.5 times maximum thickness of the lower ring.

16. A polishing head assembly comprising:
a polishing head configured to be installed in a polishing device;
a membrane mounted on the polishing head, and configured to polish a substrate and press the substrate onto a polishing pad; and
a retainer ring mounted on a side of the polishing head facing the polishing pad,
wherein the retainer ring comprises:
an upper ring coupled to a polishing head of a polishing device and is formed of a magnetic material; and
a lower ring sharing a central axis with the upper ring, and configured to be detached from the upper ring,
wherein the upper ring comprises:
a plurality of first connectors arranged along a circumferential direction on a surface facing the lower ring; and
a groove formed at an outermost radial edge of the surface facing the lower ring, and
wherein the lower ring comprises:
a plurality of second connectors formed at positions vertically overlapping the plurality of first connectors on a surface facing the upper ring and interlocked with the plurality of first connectors; and
a magnet receptacle formed on the surface facing the upper ring and accommodating a magnet.

17. The polishing head assembly of claim 16, wherein an O-ring that is provided between the retainer ring and the polishing head.

18. The polishing head assembly of claim 16, wherein the lower ring comprises a magnetic shield that is formed on a bottom of the magnet receptacle.

19. The polishing head assembly of claim 16, wherein the lower ring further comprises
a protrusion that is formed on the surface facing the upper ring at a position vertically overlapping the groove of the upper ring, and protrudes toward the upper ring.

20. The polishing head assembly of claim 19, wherein the protrusion has a height shorter than a depth of the groove.
